(19) United States
(12) Patent Application Publication
(10) Pub. No.: US 2025/0241098 A1
(43) Pub. Date: Jul. 24, 2025

(54) DISPLAY APPARATUS, APPARATUS AND METHOD FOR MANUFACTURING THE SAME

(71) Applicant: Samsung Display Co., LTD., Yongin-si (KR)

(72) Inventors: JUNYOUNG LEE, Yongin-si (KR); JEONGWEON SEO, Yongin-si (KR); JUNWOO YOU, Yongin-si (KR); SUNG-WOON IM, Yongin-si (KR)

(21) Appl. No.: 18/907,845

(22) Filed: Oct. 7, 2024

(30) Foreign Application Priority Data
Jan. 19, 2024 (KR) 10-2024-0008897

(51) Int. Cl. H01L 33/64

(52) U.S. Cl. CPC H10H 20/8581; H10H 20/8582; H10H 20/0365

(57) ABSTRACT

An apparatus for manufacturing a display apparatus includes: a molding unit including a frame including a first surface and a second surface opposite to the first surface and in which a mask opening passing from the second surface to the first surface is defined; and a plate disposed adjacent to the first surface of the frame to define a molding space with the frame. The plate includes: a first plate which is disposed in the mask opening and in which a plurality of holes are defined; and a second plate having a plate shape and disposed on the first surface of the frame to overlap at least the plurality of holes on a plane, and the first plate moves in a direction perpendicular to each of the first surface and the second surface in a space between the first surface and the second surface of the frame.

This application claims priority to Korean Patent Application No. 10-2024-0008897, filed on Jan. 19, 2024, and all the benefits accruing therefrom under 35 U.S.C. § 119, the content of which in its entirety is herein incorporated by reference.

### BACKGROUND

### (1) Field

Embodiments of the disclosure herein relate to a display apparatus and an apparatus and a method for manufacturing the display apparatus.

### (2) Description of the Related Art

A display apparatus is used in various multimedia apparatuses such as a television, a mobile phone, a tablet computer, and a game console to provide image information to a user. The display apparatus may include a display panel for providing image information and a protection layer for protecting the display panel from the outside.

The protection layer protects the display panel against external environment by preventing the display panel from being deformed by an external impact and effectively dissipating heat generated in the display panel. The protection layer has a structure in which a plurality of functional layers are laminated to apply various functions for protecting the display panel.

Researches on a display apparatus including a single-layered protection layer having integrated various functions for protecting a display panel and a manufacturing method thereof are being conducted.

### SUMMARY

The disclosure provides a display apparatus having improved reliability by arranging a single coating layer below a display panel.

The disclosure also provides an apparatus and a method for manufacturing a display apparatus, which have improved process efficiency and reliability.

An embodiment of the invention provides an apparatus for manufacturing a display apparatus, including: a molding unit including a frame including a first surface and a second surface opposite to the first surface, where a mask opening passing from the second surface to the first surface is defined in the frame; and a plate disposed adjacent to the first surface of the frame, where a molding space is defined by the frame and the plate, in which the plate includes: a first plate disposed in the mask opening, where a plurality of holes are defined in the first plate; and a second plate having a plate shape and disposed on the first surface of the frame to overlap at least the plurality of holes on a plane, and the first plate moves in a direction perpendicular to each of the first surface and the second surface in a space between the first surface and the second surface of the frame.

In an embodiment, the second plate may be coupled to the frame in a separable manner.

In an embodiment, the second plate may include a plurality of protrusions inserted into the plurality of holes defined in the first plate, respectively.

In an embodiment, the apparatus may further include a control unit which controls a movement of the first plate.

In an embodiment, the molding unit may further include a support disposed in the mask opening and connected to the frame to divide the mask opening into a plurality of openings.

In an embodiment, the support may be integrally formed with the frame as a single unitary and indivisible part.

In an embodiment, the mask opening may include a first opening and a second opening, which are separated from each other by the support, the first plate may include: a first sub-plate disposed in the first opening; and a second sub-plate disposed in the second opening, and each of the first sub-plate and the second sub-plate may move in the direction perpendicular to each of the first surface and the second surface.

In an embodiment, a mother panel may be disposed on the second surface of the frame, the mother panel may include: one surface; an opposing surface opposite to the one surface; a substrate disposed between the one surface and the other surface; and a display element layer disposed on the substrate to face the one surface and between the one surface and the opposing surface to overlap the mask opening, and the opposing surface of the mother panel may contact the frame.

In an embodiment, the first plate may include a metal.

In an embodiment, the first plate may include a same material as the frame.

In an embodiment of the invention, a method for manufacturing a display apparatus includes: preparing a molding unit including a frame in which a mask opening passing from a first surface to a second surface thereof, which face each other, is defined, a first plate which is disposed in the mask opening and in which a plurality of holes are defined, and a second plate having a plate shape and disposed on the first surface of the frame to overlap the plurality of holes on a plane; providing a resin into a molding space defined by the frame, the first plate, and the second plate in a state in which the second surface of the molding unit is arranged to face upward; arranging a mother panel on the second surface of the frame; reversing the molding unit and the mother panel upside down such that the first surface of the frame faces upward in a state in which the mother panel is disposed on the second surface of the frame; exposing the plurality of holes defined in the first plate by removing the second plate; curing the resin by supplying heat to the resin; pressing the resin by moving the first in a direction towards the mother panel; and removing the molding unit.

In an embodiment, the supplying the heat to the resin and the pressing of the resin may be simultaneously performed.

In an embodiment, the mother panel may include: one surface; an opposing surface opposite to the one surface; a substrate disposed between the one surface and the opposing surface; and a display element layer disposed on the substrate to face the one surface and between the one surface and the opposing surface to overlap the mask opening, and the opposing surface of the mother panel may contact the frame.

In an embodiment, a protection layer may be formed through the curing the resin and the pressing the resin, and the protection layer may have a thickness less than a thickness of the resin before the curing the resin.

In an embodiment, in the pressing the resin, a pattern corresponding to the plurality of holes may be formed on a bottom surface of the protection layer, which is spaced apart from the mother panel.

In an embodiment, the mother panel may include a plurality of unit panels, and the molding unit may further include a support disposed in the mask opening to divide the mask opening into a plurality of openings corresponding to the plurality of unit panels, respectively.

In an embodiment, the first plate may include a plurality of sub-plates disposed in the plurality of openings, respectively.

In an embodiment, the method may further include cutting the mother panel along a cutting line corresponding to an edge of each of the plurality of unit panels after the removing of the molding unit.

In an embodiment, the resin may include a base resin including a thermosetting resin and a plurality of fillers dispersed in the base resin.

In an embodiment of the invention, a display apparatus includes: a display panel; and a protection layer including a base layer disposed on a rear surface of the display panel and including a thermosetting resin and a plurality of fillers dispersed in the base layer, in which the protection layer has a top surface adjacent to the rear surface of the display panel and a bottom surface opposite to the top surface and is spaced apart from the rear surface, and the protection layer includes a plurality of grooves defined on the bottom surface thereof.

### BRIEF DESCRIPTION OF THE DRAWINGS

The above and other features of embodiments of the invention will become more apparent by describing in further detail embodiments thereof with reference to the accompanying drawings, in which:

FIG. 1 is a perspective view illustrating a display apparatus according to an embodiment of the invention;

FIG. 2 is an exploded perspective view illustrating the display apparatus according to an embodiment of the invention;

FIG. 3 is a cross-sectional view illustrating the display apparatus according to an embodiment of the invention;

FIG. 4 is a cross-sectional view illustrating a display module according to an embodiment of the invention;

FIGS. 5A and 5B are schematic exploded perspective views illustrating an apparatus for manufacturing the display apparatus according to an embodiment of the invention;

FIGS. 6A to 6C are cross-sectional views illustrating one component of the apparatus for manufacturing the display apparatus according to an embodiment of the invention;

FIGS. 7A and 7B are plan views illustrating the apparatus for manufacturing the display apparatus according to an embodiment of the invention;

FIG. 8 is a plan view illustrating a mother panel according to an embodiment of the invention;

FIG. 9 is a cross-sectional view taken along line II-II′ of FIG. 8;

FIGS. 10A and 10B are plan views illustrating one component of the apparatus for manufacturing the display apparatus according to an embodiment of the invention; and

FIGS. 11A to 11J are schematic views illustrating processes of a method for manufacturing the display apparatus according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when one component (or region, layer, portion) is referred to as being ‘on’, ‘connected to’, or ‘coupled to’ another component, it can be directly disposed/connected/coupled on/to the one component, or an intervening third component may also be present.

In this application, it will be understood that when a layer, a film, a region, or a plate is “directly contact” another layer, film, region, or plate, further another layer, film, region, or plate can not be present therebetween. It will also be understood that when an element or layer is referred to as being ‘on’ another one, it can be directly on the other one, or one or more intervening elements or layers may also be present.

Like reference numerals refer to like elements throughout. Also, in the figures, the thickness, ratio, and dimensions of components are exaggerated for clarity of illustration.

It will be understood that although the terms such as ‘first’ and ‘second’ are used herein to describe various elements, these elements should not be limited by these terms. Terms are only used to distinguish one component from other components. For example, a first element referred to as a first element in one embodiment can be referred to as a second element in another embodiment without departing from the scope of the appended claims. The terms of a singular form may include plural forms unless referred to the contrary.

Also, spatially relative terms, such as “below”, “lower”, “above”, and “upper”, may be used herein for ease of description to describe an element and/or a feature's relationship to another element(s) and/or feature(s) as illustrated in the drawings. The terms may be a relative concept and described based on directions expressed in the drawings.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be understood that the term “includes” and/or “including” or “comprises” and/or “comprising”, when used in this specification, specifies the presence of stated features, integers, steps, operations, elements, components, or a combination thereof, but does not preclude the presence or addition of one or more other features, integers, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as generally understood by those skilled in the art. Terms as defined in a commonly used dictionary should be construed as having the same meaning as in an associated technical context, and unless defined apparently in the description, the terms are not ideally or excessively construed as having formal meaning.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

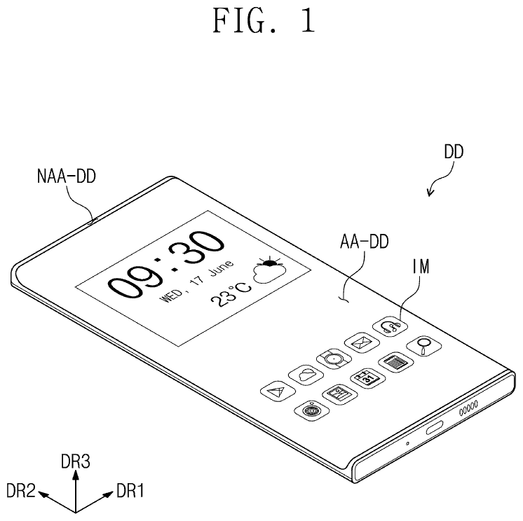

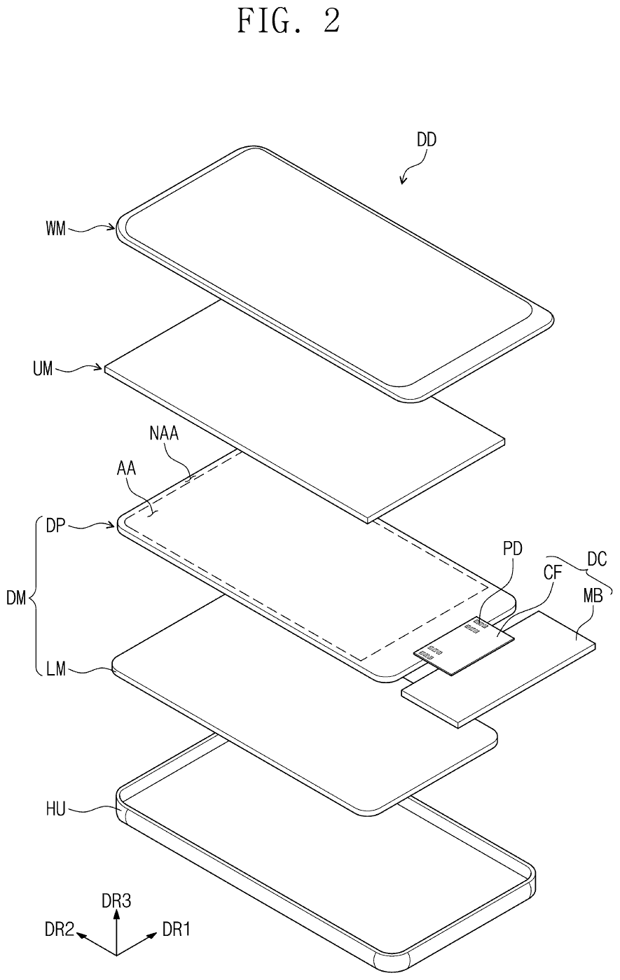

FIG. 1 is a perspective view of a display apparatus according to an embodiment of the invention. FIG. 2 is an exploded perspective view of the display apparatus illustrated in FIG. 1.

Referring to FIG. 1, an embodiment where a display apparatus DD is a mobile phone is shown as an example. However, the embodiment of the invention is not limited to the display apparatus DD. In an embodiment, for example, the display apparatus DD may be a small or medium-sized display apparatus such as a tablet computer, a navigation system for a vehicle, a game console, a wearable device, or a camera.

The display apparatus DD may display an image IM through an active area AA-DD. The active area AA-DD may include a plane defined by a first direction DR1 and a second direction DR2. The active area AA-DD may further include a curved surface bent from one side of the plane defined by the first direction DR1 and the second direction DR2. The display apparatus DD according to an embodiment, as illustrated in FIG. 1, includes two curved surfaces bent from both opposing side surfaces, respectively, of the plane defined by the first direction DR1 and the second direction DR2. However, the embodiment of the invention is not limited to the shape of the active area AA-DD. In an embodiment, for example, the active area AA-DD may include only the plane or may further include at least two curved surfaces, e.g., four curved surfaces bent from four side surfaces of the plane, respectively.

Although the first direction DR1 to a fourth direction DR4 are illustrated in FIG. 1 and drawings below, directions indicated by the first to fourth directions DR1, DR2, DR3, and DR4, as relative concepts, may be converted with respect to each other.

In this specification, a top surface of each component is parallel to the plane defined by the first direction DR1 and the second direction DR2. A thickness direction of each component indicates a third direction DR3. The fourth direction DR4 is opposite to the third direction DR3. The third direction DR3 represents an upward direction, and the fourth direction DR4 represents a downward direction. Also, an upper side (or upper portion) and a lower side (or lower portion) of each component is distinguished by the third direction DR3 and the fourth direction DR4. In this embodiment, an expression “on a plane” may represent when viewed on the plane defined by the first direction DR1 and the second direction DR2, that is, when viewed in the third direction DR3.

The display apparatus DD may include the active area AA-DD and a peripheral area NAA-DD disposed adjacent to the active area AA-DD. The active area AA-DD may correspond to a display area AA (refer to FIG. 2) of a display panel DP that will be described later, and the peripheral area NAA-DD may correspond to a non-display area NAA (refer to FIG. 2) of the display panel DP.

The peripheral area NAA-DD that blocks an optical signal may be disposed outside the active area AA-DD to surround the active area AA-DD. In an embodiment, the peripheral area NAA-DD may be disposed on a side surface of the display apparatus DD instead of a front surface thereof. In an embodiment, the peripheral area NAA-DD may be omitted.

Referring to FIGS. 1 and 2, an embodiment of the display apparatus DD may include a window WM, a housing HU, a display module DM, a circuit board DC, and an upper member UM.

The display apparatus DD according to an embodiment may include the window WM disposed on the display module DM. The window WM may be disposed at an outer surface of the display apparatus DD or defines an exterior surface of the display device DD. Although not shown, the window WM may include a base substrate and further include functional layers such as an anti-reflection layer, an anti-fingerprint layer, and an optical layer controlling a phase.

The upper member UM of the display apparatus DD may be disposed between the window WM and the display module DM. The upper member UM may include an anti-reflection layer and an input detection sensor. The anti-reflection layer may reduce a reflectance of external light. The input detection sensor may detect an external input of a user. The upper member UM may further include an adhesive layer that couples the anti-reflection layer and the input detection sensor.

The display module DM may be disposed below the upper member UM. The display module DM may include the display panel DP and a protection layer LM disposed below the display panel DP.

The display panel DP includes the display area AA on which the image IM is displayed and the non-display area NAA disposed adjacent to the display area AA. That is, a front surface of the display panel DP may include the display area AA and the non-display area NAA. The display area AA may be activated by an electric signal.

The non-display area NAA may be adjacent to the active area AA. The non-display area NAA may surround the display area AA. A driving circuit or driving wire for driving the display area AA, various signal lines or pads that provide electrical signals to the display area AA, or electronic elements may be disposed in the non-display area NAA.

The display panel DP may include a light emitting element layer DP-ED (refer to FIG. 9) containing an organic light emitting element, a quantum dot light emitting element, a micro-LED light emitting element, or a nano-LED light emitting element. The light emitting element layer DP-ED (refer to FIG. 9) may be a component that substantially generates an image.

The display apparatus DD may include a circuit board DC connected to the display panel DP. The circuit board DC may include a flexible board CF and a main board MB. The flexible board CF may include an insulating film and a conductive wire mounted on the insulating film. The conductive wire may be connected to the pads PD to electrically connect the circuit board DC and the display panel DP. In an embodiment, the flexible board CF may be omitted, and, in this case, the main board MB may be directly connected to the display panel DP.

The main board MB may include signal lines and electronic elements, which are not illustrated. The electronic elements may be connected to the signal lines and electrically connected to the display panel DP. The electronic elements may generate various electrical signals such as a signal for generating the image IM or a signal for detecting an external input or process detected signals. Also, the main board MB may be provided in plurality to correspond to each electrical signal for generating and processing. However, the embodiment of the invention is not limited thereto.

The protection layer LM may be disposed below the display panel DP. The protection layer LM may support the display panel DP and perform a heat dissipation function that dissipates heat generated from the display panel DP. The protection layer LM will be described in detail with reference to FIG. 4

The housing HU may be disposed below the display module DM. The display module DM or the like may be accommodated in the housing HU. The housing HU may be coupled with the window WM to define an external appearance of the display apparatus DD.

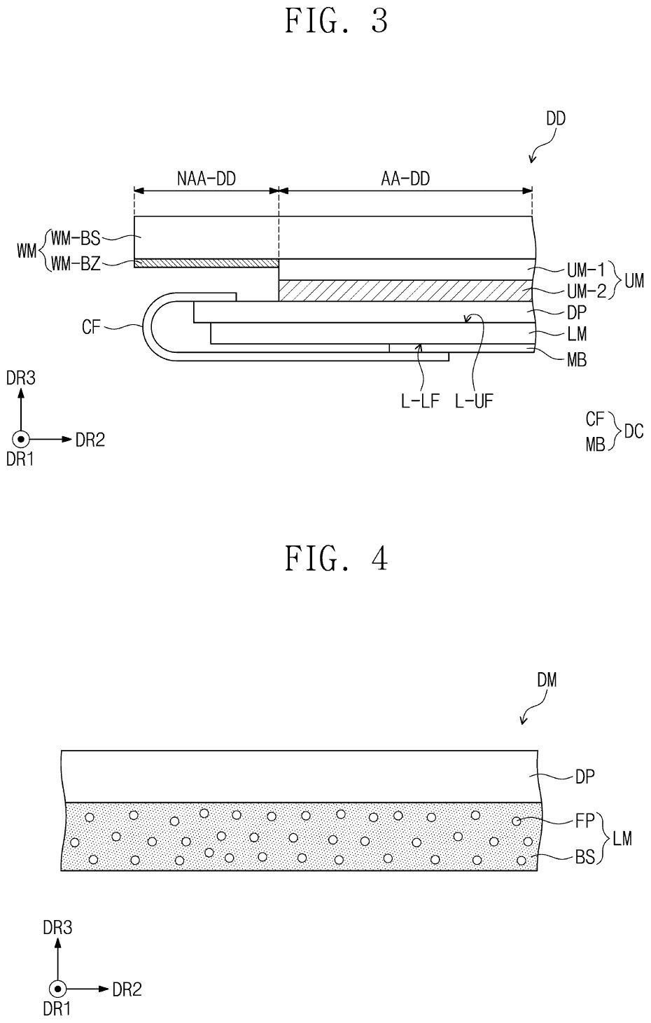

FIG. 3 is a cross-sectional view illustrating some components of the display apparatus DD according to an embodiment of the invention. FIG. 4 is a cross-sectional view illustrating a display module according to an embodiment of the invention. Particularly, FIG. 4 is a cross-sectional view illustrating the display panel DP and the protection layer LM among the components of the display apparatus.

Referring to FIG. 3, the display apparatus DD according to an embodiment of the invention may include a window WM, an upper member UM, a display panel DP, a circuit board DC, and a protection layer LM.

In an embodiment, the window WM may cover a front surface of the display panel DP. The window WM may include a base substrate WM-BS and a bezel pattern WM-BZ. The base substrate WM-BS includes a transparent first base layer such as a glass substrate or a transparent film. The bezel pattern WM-BZ may have a multi-layer structure. The multi-layer structure may include a colored color layer and a black light shielding layer. The colored color layer and the black light shielding layer may be provided through a deposition, printing, or coating process. In another embodiment, the bezel pattern WM-BZ may be omitted from the window WM and provided to the upper member UM instead of the base substrate WM-BS.

In an embodiment, the upper member UM include an anti-reflection layer UM-1 and an input sensor UM-2.

The anti-reflection layer UM-1 may reduce a reflectance of external light. The anti-reflection layer UM-1 may include a retarder and/or a polarizer. The anti-reflection layer UM-1 may include polarizing films or color filters. The color filters may have a predetermined arrangement. The arrangement of the color filters may be determined in consideration of emitted colors of pixels contained in the display panel DP. The anti-reflection layer UM-1 may further include a division layer adjacent to the color filters.

The input sensor UM-2 may include a plurality of electrodes (not shown) for detecting an external input, trace lines (not shown) connected to the plurality of electrodes, and an organic layer and/or an inorganic layer for insulating/protecting the plurality of electrodes or the trace lines. In an embodiment, the input sensor UM-2 may be a capacitive sensor, but the embodiment of the invention is not limited thereto.

In an embodiment, the input sensor UM-2 may be directly provided on an encapsulation layer through a continuous process when the display panel DP is manufactured. However, the embodiment of the invention is not limited thereto. in another embodiment, for example, the input senser UM-2 may be manufactured as a panel separated from the display panel DP and then attached to the display panel DP by an adhesive layer.

In an embodiment, an adhesive layer (not shown) may be additionally disposed between the window WM and the anti-reflection layer UM-1, and an adhesive layer may be additionally disposed between the anti-reflection layer UM-1 and the input sensor UM-2. Each of the window WM, the anti-reflection layer UM-1, and the input sensor UM-2 may be coupled through the adhesive layers.

In an embodiment, the circuit board DC may include a flexible board CF and a main board MB. The flexible board CF according to an embodiment may be assembled in a bent state. Accordingly, the main board MB may be disposed on a rear surface of the display panel DP and stably accommodated in a space provided by the housing HU (refer to FIG. 2). In an embodiment, for example, the flexible board CF may be bent toward the rear surface of the display panel DP and disposed below the protection layer LM. However, the embodiment of the invention is not limited thereto. In another embodiment, the flexible board CF may be omitted, and, in this case, the main board MB may be disposed directly below the protection layer LM or mounted in the protection layer LM.

The protection layer LM is disposed below the display panel DP. The protection layer LM may be disposed directly below the display panel DP to contact a bottom surface of the display panel DP. The protection layer LM may contact the circuit board DC. In an embodiment, for example, the protection layer LM may contact the circuit board MB.

Referring to FIGS. 3 and 4, the window LM may be disposed on the bottom surface of the display panel DP. The protection layer LM may have a top surface L-UF adjacent to the bottom surface of the display panel DP and a bottom surface L-LF opposite to the top surface L-UF and spaced apart from the bottom surface of the display panel DP. In the display module DM according to an embodiment of the invention, as shown in FIG. 4, only the protection layer LM may be disposed below the display panel DP. That is, a lowermost surface of the display module DM may be defined by the bottom surface L-LF of the protection layer LM. Accordingly, a thickness of the display apparatus DD including the display module DM according to an embodiment may be reduced, components thereof may be simplified, and an efficiency of a process for manufacturing the display apparatus DD according to an embodiment may increase.

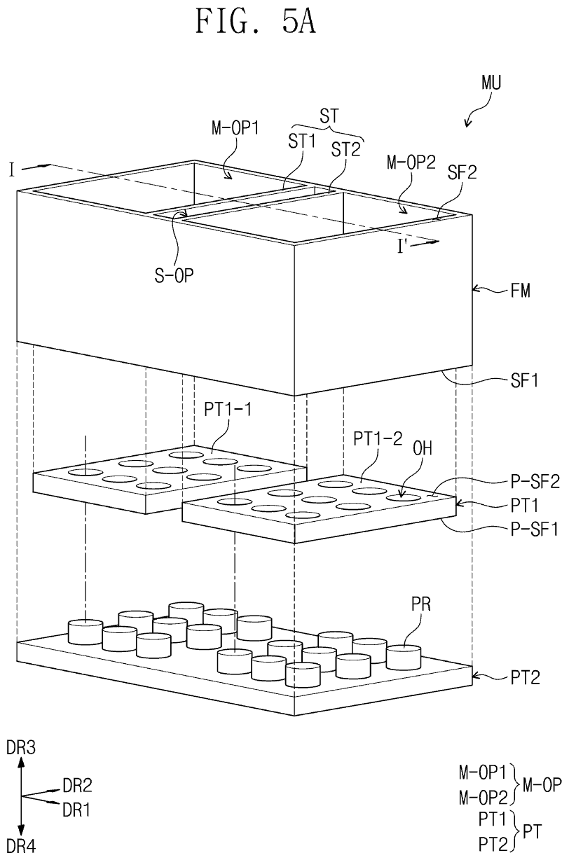

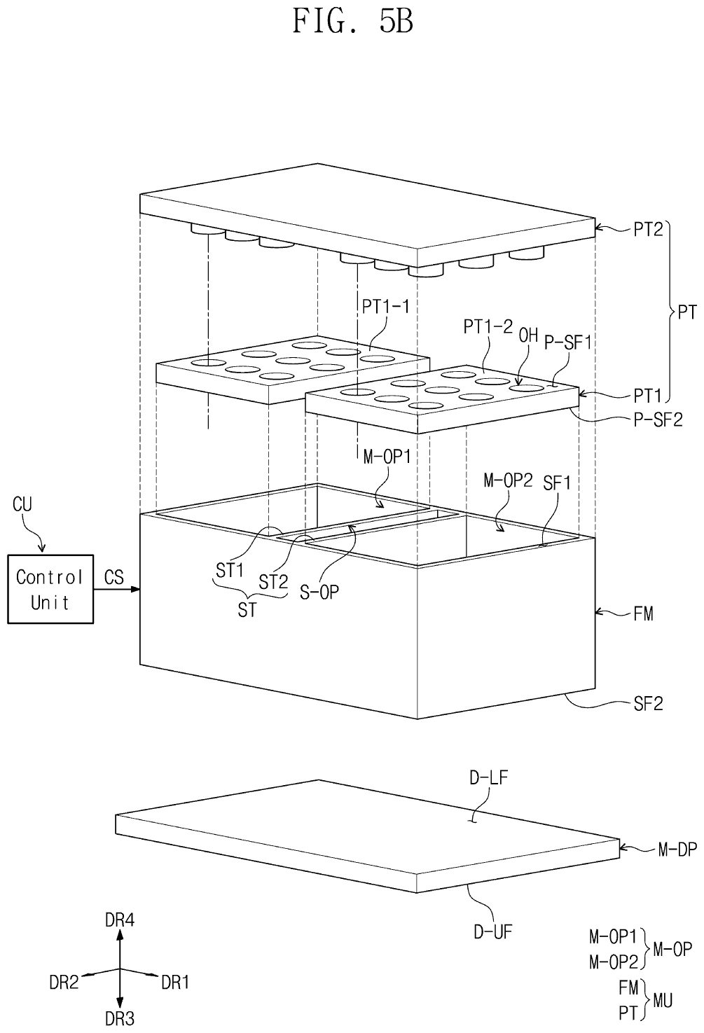

In an embodiment, a predetermined pattern may be provided on the bottom surface L-LF of the protection layer LM. The pattern may correspond to a transfer pattern provided in a process of pressing resin by a plate in which a plurality of holes are defined when curing the resin for providing the protection layer LM. When the resin is pressed by the plate in which the plurality of holes are defined, a curing speed and a solvent evaporation rate may be different between a portion of the resin, which overlaps the plurality of holes, and a portion of the resin, which does not overlap the plurality of holes. Accordingly, a pattern corresponding to a shape of the hole defined in the plate may be provided on the bottom surface of the protection layer LM. The pattern may have a shape recessed or protruding from the bottom surface of the protection layer LM. A method of forming the protection layer LM will be described in detail later with reference to FIG. 5A.

In an embodiment, as shown in FIG. 4, the protection layer LM may include a base layer BS and a plurality of fillers FP dispersed in the base layer BS. The protection layer LM may be a single layer including the base layer BS and the plurality of fillers FP. The plurality of fillers FP may be fillers dispersed in the base layer BS.

As the protection layer LM includes the base layer BS and the plurality of fillers FP, the protection layer LM may perform a plurality of functions in the display module DM. For example, the protection layer LM may support the display panel DP. The protection layer LM may protect the display panel DP from a physical impact applied from the outside of the display apparatus DD (refer to FIG. 1). The protection layer LM may perform a heat dissipation function to radiate heat generated in the display panel DP. The protection layer LM may perform an electromagnetic wave blocking function. The protection layer LM may perform a light blocking function. However, the embodiment of the invention is not limited to the function of the protection layer LM. For example, the protection layer LM may additionally perform other functions depending on thicknesses and materials of the protection layer LM. As the single-layered protection layer LM performs the functions of supporting the display panel DP, dissipating heat, and blocking an electromagnetic wave, the display apparatus DD (refer to FIG. 1) may have a reduced thickness, have simplified components, and increase an efficiency in a process of manufacturing the display apparatus DD (refer to FIG. 1).

The protection layer LM may have a thickness of about 30 micrometers (μm) or greater to about 300 μm or less. The protection layer LM may have a viscosity of about 100 centipoise (cps) or greater to about 100,000 cps or less. In an embodiment, for example, the protection layer LM may have a viscosity of about 3,000 cps. Accordingly, the protection layer LM may support the display panel DP in the display module DM.

Each of the plurality of fillers FP may include an organic material or inorganic material. In an embodiment, for example, each of the plurality of fillers FP may include graphite or metal particles. Each of the plurality of fillers FP may perform a same function as each other or different functions from each other. Accordingly, the protection layer LM may perform the plurality of functions of the display apparatus DD (refer to FIG. 1), such as supporting, heat dissipating, light blocking, and electromagnetic wave blocking.

In an embodiment, the plurality of fillers FP may include a light blocking material. The protection layer LM may have a black color as the protection layer LM includes the plurality of fillers FP including or formed of the light blocking material. The light blocking material may be a black pigment or a black dye as an example. Alternatively, the light blocking material may be a carbon-based material such as graphene or graphite. In such an embodiment where the plurality of fillers FP include the light blocking material, the protection layer LM may effectively prevent light emitted from the display panel DP from being leaked downward from the display panel DP.

The plurality of fillers FP may have a mean diameter of about 1 um or greater to about 70 μm or less. In an embodiment, for example, each of the plurality of fillers FP may have a mean diameter of about 10 μm or greater to about 50 μm or less. In an embodiment, the fillers FP have a substantially same diameter as each other as shown in FIG. 4, but the embodiment of the invention is not limited thereto. In an embodiment, for example, the fillers FP may have a substantial monodisperse distribution or a polydisperse distribution obtained by mixing a plurality of particles having the monodisperse distribution.

The plurality of fillers FP may have a content of about 30 weight percent (wt %) or greater and about 80 wt % or less with respect to entire materials included in the protection layer LM. In an embodiment, for example, the plurality of fillers FP may have a content of about 50 wt % or greater and about 80 wt % or less with respect to the entire materials included in (or a total content of) the protection layer LM.

The base layer BS may provide a base material in which the plurality of fillers FP are dispersed. The base layer BS may include an organic material. The base layer BS may include at least one selected from an acrylic-based polymer, a urethane-based polymer, a silicon-based polymer, and an imide-based polymer. The base layer BS may include a material having a predetermined strength or rigidity.

In an embodiment, the base layer BS may include a curable resin. In an embodiment, for example, the base layer BS may include a thermosetting resin. In an embodiment where the plurality of fillers FP include a light blocking material, a light transmittance may be reduced, and thus a light curing efficiency of the resin for providing the protection layer LM may be reduced. That is, when the protection layer LM is provided by using a photocuring method, light in an ultraviolet wavelength range used as a light source may be absorbed by the light blocking material included in the plurality of fillers FP, thereby reducing an exposure sensitivity of the protection layer LM. An embodiment of the invention may use a thermal curing method for providing the protection layer LM to exhibit a high curing efficiency although the plurality of fillers FP include the light blocking material, thereby effectively preventing an uncured base resin from remaining in the protection layer LM. Thus, durability and reliability of the protection layer LM may be improved.

The display apparatus DD according to an embodiment of the invention may include the protection layer LM that performs multiple functions below of the display panel DP to obtain an effect of reducing the thickness and simplifying the components of the display apparatus DD. Since the display panel DP includes a light emitting element which causes various side effects, a typical display apparatus DD typically further includes a plurality of functional members or layers below the display panel DP, such as a shielding layer, a heat dissipation layer, a cushion layer, and a support layer to compensate such side effects. In an embodiment of the invention, the protection layer LM that performs the above-described functions is provided such that an effect of reducing the thickness, simplifying components, and increasing a manufacturing process efficiency may be obtained while performing functions of a plurality of typical functional layers. The display apparatus DD according to an embodiment of the invention may have an increased impact resistance of the display panel DP against an external impact by arranging the protection layer LM below the display panel DP.

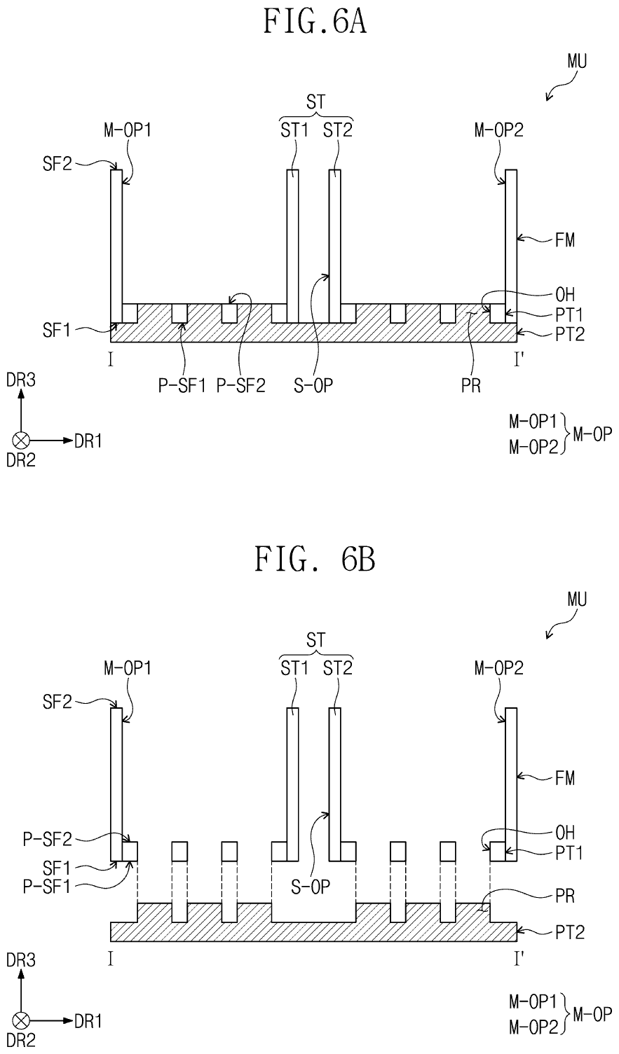

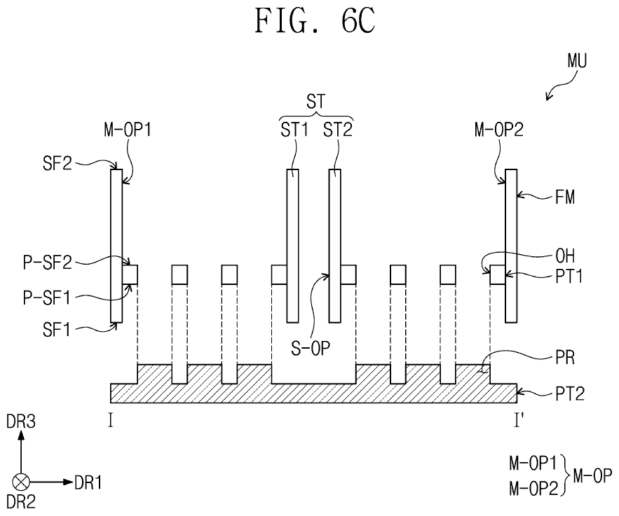

FIGS. 5A and 5B are schematic exploded views illustrating the display apparatus according to an embodiment of the invention. Particularly, FIG. 5B is a perspective view illustrating a reverse state of an apparatus for manufacturing the display apparatus illustrated in FIG. 5A. In FIG. 5B, a mother panel M-DP that is an object to be processed is illustrated together with the apparatus for manufacturing the display apparatus. FIGS. 6A to 6C are cross-sectional views illustrating a molding unit MU of the apparatus for manufacturing the display apparatus according to an embodiment of the invention. FIGS. 6A to 6C are cross-sectional views taken along line I-I′ in FIG. 5A.

Referring to FIGS. 5A, 5B, and 6A to 6C, the apparatus for manufacturing the display apparatus according to an embodiment of the invention may include the molding unit MU. The molding unit MU may include a frame FM and a plate PT. The plate PT may include a first plate PT1 and a second plate PT2. The molding unit MU may provide a molding space defined therein by the frame FM and the plate PT. The molding space may represent a space in which a resin RS that will be described later is processed. The molding space defined by the frame FM and the plate PT may have a planar shape corresponding to that of the protection layer LM illustrated in FIG. 2.

The frame FM may constitute a sidewall of the molding unit MU. The frame FM may include a first surface SF1 and a second surface SF2 opposite to the first surface SF1. The first surface SF1 may define a bottom surface of the frame FM, and the second surface SF2 may define a top surface of the frame FM. Each of the first surface SF1 and the second surface SF2 may be parallel to a plane defined by the first direction DR1 and the second direction DR2. A mask opening M-OP passing or extending through the frame FM in a direction from the first surface SF1 to the second surface SF2, i.e., a thickness direction, may be defined in the frame FM. The mask opening M-OP may be defined by an inner surface of the frame FM. The inner surface of the frame FM may extend in the thickness direction and be connected to each of the first surface SF1 and the second surface SF2.

In an embodiment, the frame FM may include a metal material. In an embodiment, for example, the frame FM may include stainless steel (SUS).

The plate PT may be disposed adjacent to the first surface SF1 of the frame FM. The plate PT and the frame FM may define the molding space. The plate PT may be coupled with the frame FM to define the molding space. A molding material such as a resin may be filled into the molding space defined by the plate PT and the frame FM. The plate PT includes a first plate PT1 and a second plate PT2, which are separable from each other.

In an embodiment, as illustrated in FIGS. 6A to 6C, the first plate PT1 may be disposed in the mask opening M-OP defined in the frame FM. The first plate PT1 may move in a vertical direction in the molding space. The first plate PT1 may move between the first surface SF1 and the second surface SF2 in the mask opening M-OP of the frame FM. The first plate PT1 may move in a direction perpendicular to each of the first surface SF1 and the second surface SF2 between the first surface SF1 and the second surface SF2, i.e., in the third direction DR3 or the fourth direction DR4. The first plate PT1 may move away from or close to the second surface SF2 of the frame FM to vary a volume of the molding space.

In an embodiment, the first plate PT1 may include a same material as the frame FM. The first plate PT1 may include metal. In an embodiment, for example, the first plate PT1 may include stainless steel (SUS).

In an embodiment, the apparatus for manufacturing the display apparatus according to an embodiment may further include a control unit (or controller) CU that controls or adjusts a movement of the first plate PT1. The molding unit MU may be connected to the control unit CU through a cable or through a wireless communication module to transmit thereto and receive an electrical signal therefrom. The molding unit MU may receive a control signal CS from the control unit CU to change a position of the first plate PT1 in the vertical direction. Here, the control unit CU may be any conventional controller including a circuitry for generating a control signal for a motion control of a plate.

A plurality of holes OH may be defined in the first plate PT1. The plurality of holes OH may serve to improve heat transfer to a molding material when the molding material is cured. Also, the plurality of holes OH may serve to easily discharge a solvent evaporated when the molding material is cured. The first plate PT1 may have a bottom surface P-SF1 adjacent to the second plate PT2 and a top surface P-SF2 opposite to the bottom surface P-SF1. In an embodiment, each of the plurality of holes OH may be defined through the first plate PT1 from the top surface P-SF2 of the first plate PT1 to the bottom surface P-SF1 of the first plate PT1 as illustrated in FIGS. 5A and 5B. Each of the plurality of holes OH may have a circular shape on a plane defined by the first direction DR1 and the second direction DR2 or when viewed in the vertical direction. However, the embodiment of the invention is not limited to the shape of each of the plurality of holes OH. Each of the plurality of holes OH may have one of other various shapes such as a polygonal shape, an elliptical shape, and a striped shape. In an embodiment, the plurality of holes OH may be spaced from each other at a constant distance or interval as shown in FIGS. 5A and 5B, but the embodiment of the invention is not limited thereto. In another embodiment, for example, the plurality of holes OH may be from each other at an arbitrary distance.

The second plate part PT2 may have a plate shape. The second plate PT2 may be disposed on the first surface SF1 of the frame FM to overlap the plurality of holes OH defined in the first plate PT1 on the plane defined by the first direction DR1 and the second direction DR2. The second plate PT2 may contact the first surface SF1 of the frame FM. The second plate PT2 may overlap the plurality of holes OH. The second plate PT2 may be disposed to overlap the plurality of holes OH and serve to prevent a molding material filled in the molding space from leaking out of the plurality of holes OH.

In an embodiment, the second plate PT2 may include a same material as the frame FM. The second plate PT2 may include metal. In an embodiment, for example, the second plate PT2 may include stainless steel (SUS). However, the embodiment of the invention is not limited to the material of the second plate PT2.

As illustrated in FIGS. 6A to 6C, the second plate PT2 may be separably coupled with the frame FM. The second plate PT2 may be coupled to the first surface SF1 of the frame FM. Various sorts of coupling methods may be used to separate the second plate PT2 and the frame FM. In an embodiment, for example, the second plate PT2 may be coupled to and fixed to the frame FM by a mechanical fastening method such as screw fastening.

In an embodiment, the second plate PT2 may further include a plurality of protrusions PR. The second plate PT2 may include a top surface adjacent to the frame FM and a bottom surface opposite to the top surface. The plurality of protrusions PR may be disposed on the top surface of the second plate PT2 adjacent to the first plate PT1. The plurality of protrusions PR may have a shape protruding from the top surface of the second plate PT2 in the third direction DR3. The plurality of protrusions PR may have an integrated shape with a base plate of the second plate PT2.

The plurality of protrusions PR may correspond to the plurality of holes OH defined in the first plate PT1, respectively. Each of the plurality of protrusions PR may have a height equal to the thickness of the first plate PT1. However, the embodiment of the invention is not limited thereto. In an embodiment, for example, each of the plurality of protrusions PR may have a height greater or less than the thickness of the first plate PT1. The plurality of protrusions PR may be inserted into the plurality of holes OH, respectively. The plurality of protrusions PR may have a shape corresponding to that of the plurality of holes OH. The protrusions PR may have various shapes depending on the shapes of the holes OH.

The plurality of protrusions PR may be inserted in an upward direction from below the molding unit MU. The plurality of protrusions PR may be coupled to the plurality of holes OH to provide a bottom surface of the molding unit MU, which contacts the molding material. The bottom surface provided by the coupling of the protrusions PR and the holes OH may be connected to an inner surface of the frame FM to define a molding space. Each of the bottom surface provided by the coupling of the protrusions PR and the holes OH and the inner surface of the frame FM may contact the molding material.

In an embodiment, the molding unit MU may further include a support ST that divides the mask opening M-OP into a plurality of openings. The support ST may be disposed in the mask opening M-OP. The support SP may be connected to the frame FM. The support SP may be connected to an inner surface of the frame FM. The support ST may have an integrated shape with the frame FM, or be integrally formed with the frame FM as a single unitary indivisible part. In an embodiment, a thickness of the support ST in the third direction DR3 may be substantially equal to that of the frame FM in the third direction DR3. However, the embodiment of the invention is not limited thereto. In another embodiment, for example, the thickness of the support ST in the third direction DR3 may be different from that of the frame FM in the third direction DR3.

As illustrated in FIGS. 5A and 5B, the mask opening M-OP defined in the frame FM may include a first opening M-OP1 and a second opening M-OP2, which are divided by the support ST. The first opening M-OP1 and the second opening M-OP2, which are divided by the support ST, may have a same area as each other on the plane. However, the embodiment of the invention is not limited thereto. In an embodiment, for example, a position of the support ST may be variously changed in the mask opening M-OP depending on a design of an area of the molding space.

In an embodiment, the first plate PT1 may be provided in plurality. As the mask opening M-OP is divided into a plurality of openings by the support ST, the first plate PT1 may be provided in plurality in correspondence to the openings. In an embodiment, for example, the first plate PT1 may include a plurality of sub-plates corresponding to a plurality of divided openings. Each of the plurality of sub-plates may be disposed in the corresponding opening to be movable in the vertical direction.

As illustrated in FIGS. 5A and 5B, the first plate PT1 may include a first sub-plate PT1-1 corresponding to the first opening M-OP1 and a second sub-plate PT1-2 corresponding to the second opening M-OP2. The first sub-plate PT1-1 may be disposed in the first opening M-OP1. The second sub-plate PT1-2 may be disposed in the second opening M-OP2. Each of the first sub-plate PT1-1 and the second sub-plate PT1-2 may move in the direction perpendicular to each of the first surface SF1 and the second surface SF2 between the first surface SF1 and the second surface SF2 of the frame FM.

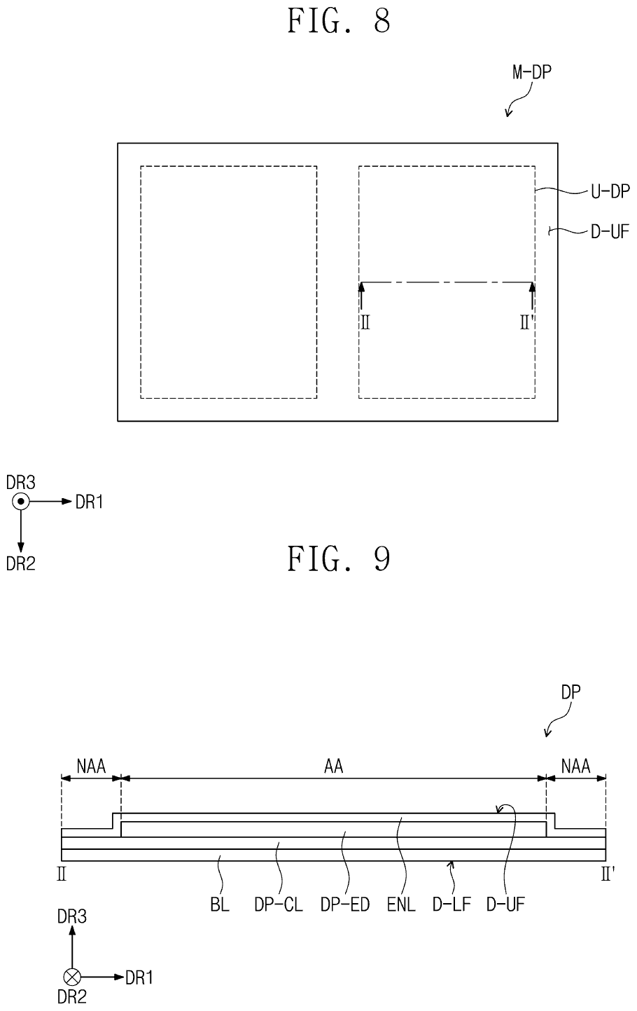

Referring to FIG. 5B, the mother panel M-DP that is an object to be processed may be disposed on the second surface SF2 of the frame FM. The mother panel M-DP may be seated and fixed on the second surface SF2 of the frame FM. The mother panel M-DP may include or be divided into a plurality of unit panels U-DP (refer to FIG. 8). The mother panel M-DP will be described in detail later with reference to FIGS. 8 to 9.

The mother panel M-DP may include one surface D-UF and the other surface (or an opposing surface) D-LF opposite to the one surface D-UF. In this specification, the one surface D-UF may correspond to the top surface of the mother panel M-DP, and the other surface D-LF may correspond to the bottom surface of the mother panel M-DP. Each of the one surface D-UF and the other surface D-LF may be parallel to the plane defined by the first direction DR1 and the second direction DR2. A plurality of protection layers LM (refer to FIG. 2) may be provided on the other surface D-LF of the mother panel M-DP by the apparatus for manufacturing the display apparatus according to an embodiment.

In an embodiment, the apparatus for manufacturing the display apparatus according to an embodiment may further include a driving unit (not shown) that reverses the mother panel M-DP and the molding unit MU in the vertical direction in a state in which the mother panel M-DP is seated on the second surface SF2 of the frame FM. The driving unit may rotate the mother panel M-DP and the molding unit MU by 180° based on a horizontal rotation axis in a state in which the mother panel M-DP is seated on the molding unit MU. Accordingly, the mother panel M-DP and molding unit MU may be reversed in the vertical direction.

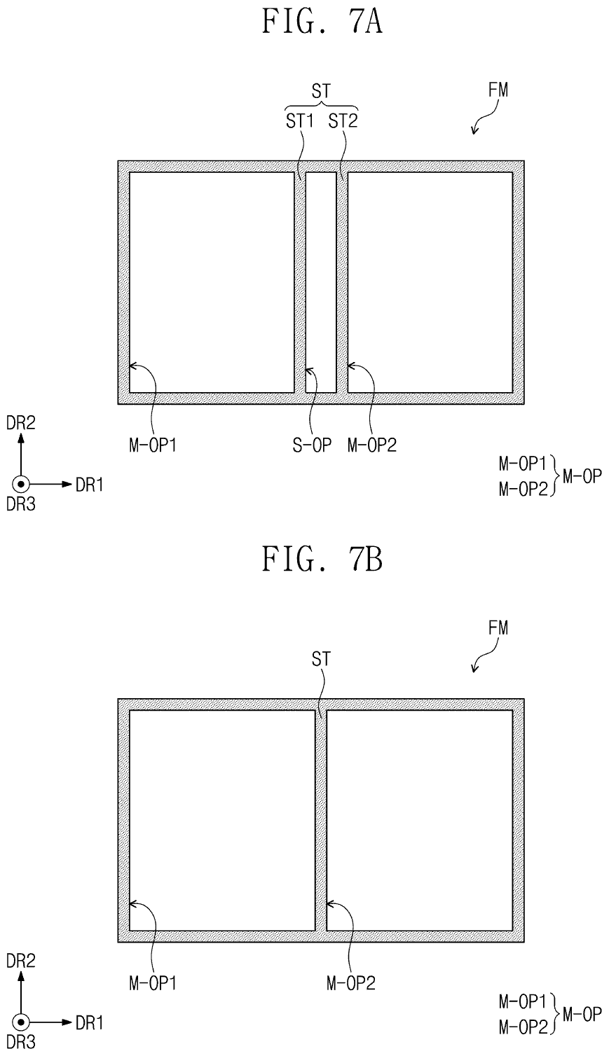

FIGS. 7A and 7B are plan views illustrating one component of the apparatus for manufacturing the display apparatus according to an embodiment of the invention. FIGS. 7A and 7B are plan views illustrating the frame FM constituting the molding unit MU.

Referring to FIGS. 5A, 5B, 7A, and 7B together, in the apparatus for manufacturing the display apparatus according to an embodiment, the molding unit MU may include a support ST. The support ST may divide the mask opening M-OP into a plurality of openings.

Referring to FIGS. 7A and 7B, the support ST may be disposed in the mask opening M-OP. The support ST may have a bar shape extending in the second direction DR2. The mask opening M-OP may be divided into the first opening M-OP1 and the second opening M-OP2 by the support ST. The first opening M-OP1 and the second opening M-OP2 may be spaced apart from each other in the first direction DR1. In an embodiment, the first opening M-OP1 and the second opening M-OP2 may have the same area on the plane.

Referring to FIGS. 7A, 7B, and 8 together, the plurality of openings divided by the support ST may correspond to the unit panels U-DP included in the mother panel M-DP, respectively. That is, the unit panels U-DP included in the mother panel M-DP illustrated in FIG. 8 may overlap the openings M-OP1 and M-OP2, respectively.

As illustrated in FIG. 7A, in an embodiment, the support ST may be provided in plurality. The support ST may include a first sub-support ST1 and a second sub-support ST2. Each of the first sub-support ST1 and the second sub-support ST2 may be disposed in the mask opening M-OP. Each of the first sub-support ST1 and the second sub-support ST2 may be connected to the frame FM. Each of the first sub-support ST1 and the second sub-support ST2 may be connected to the inner surface of the frame FM. The first sub-support ST1 and the second sub-support ST2 may have an integrated shape with the frame FM.

The mask opening M-OP may be divided into a first opening M-OP1, a second opening M-OP2, and a dummy opening S-OP by the first and second sub-support ST1 and ST2. The dummy opening S-OP may be defined between the first sub-support ST1 and the second sub-support ST2. On the plane defined by the first direction DR1 and the second direction DR2, the first opening M-OP1 and the second opening M-OP2 may be spaced apart from each other with the dummy opening S-OP therebetween.

In the apparatus for manufacturing the display apparatus according to an embodiment, the first and second openings M-OP1 and M-OP2 in the molding unit MU may be filled with a molding material. Also, as illustrated in FIG. 7A, when the dummy opening S-OP is defined between the sub-supports ST1 and ST2, the dummy opening S-OP may be also filled with the molding material. Accordingly, a resin may be disposed on a portion overlapping the dummy opening S-OP in the mother panel M-DP that is the object to be processed.

Also, in this specification, the embodiment of the invention is not limited to the number, position, and extension direction of the supports ST in FIGS. 7A and 7B, and the number, position, and extension direction of the supports ST may be variously changed depending on a molding space area design and/or the number of unit panels included in the mother panel.

FIG. 8 is a plan view illustrating the mother panel M-DP in FIG. 5B. FIG. 8 is a plan view illustrating the mother panel M-DP seen from the top surface D-UF of the mother panel M-DP in FIG. 5B. FIG. 9 is a cross-sectional view taken along line II-II′ of FIG. 8.

Referring to FIG. 8, the mother panel M-DP may include a plurality of unit panels U-DP. Each of the unit panels U-DP may correspond to the display panel DP in FIG. 2. In this specification, the unit panel U-DP may be referred to as a display panel. In FIG. 8, unit panels (U-DP) are shown as dotted lines for convenience of illustration.

Referring to FIGS. 2, 5B, and 8 together, the plurality of protection layers LM (refer to FIG. 2) overlapping the plurality of unit panels U-DP may be disposed on the bottom surface D-LF of the mother panel M-DP through the apparatus for manufacturing the display apparatus according to an embodiment. After the plurality of protection layers LM (refer to FIG. 2) are provided on the bottom surface D-LF of the mother panel M-DP, each of the plurality of unit panels U-DP may be cut into an individual unit panel U-DP. Edges of the unit panels U-DP expressed by a dotted line in FIG. 8 may correspond to cutting lines in a cutting process. The edges of the unit panels U-DP defined by the cutting lines may be cut to separate the plurality of unit panels U-DP from each other.

In an embodiment, as shown in FIG. 8, each of the plurality of unit panels U-DP may have a rectangular shape having short sides extending in the first direction DR1 and long sides extending in the second direction DR2, but the embodiment of the invention is not limited thereto.

Referring to FIG. 9, the display panel DP according to an embodiment of the invention include a base substrate BL, a circuit layer DP-CL disposed on the base substrate BL, a light emitting element layer DP-ED, and an encapsulation layer ENL. The base substrate BL may include a plastic substrate, a glass substrate, a metal substrate, and an organic/inorganic composite substrate. In an embodiment, for example, the base substrate BL may include at least one polyimide layer.

The circuit layer DP-CL includes at least one insulation layer, semiconductor patterns, and conductive patterns. The insulation layer includes at least one inorganic layer and at least one organic layer. The semiconductor patterns and the conductive patterns may constitute signal lines, a pixel driving circuit, and a scan driving circuit. Also, the circuit layer DP-CL may include a metal layer.

The light emitting element layer DP-ED includes a display element such as a light emitting element. In an embodiment, for example, the light emitting element may include an organic light emitting element, a quantum dot light emitting element, a micro-light emitting diode (LED) light emitting element, or a nano-LED light emitting element. The light emitting element layer DP-ED may further include an organic layer such as a pixel defining layer.

The light emitting element layer DP-ED may be disposed on the display area AA. The non-display area NAA may be disposed outside the display area AA to surround the display area AA, and the light emitting element may not be disposed on the non-display area NAA.

The encapsulation layer ENL may be disposed on the light emitting element layer DP-ED to cover the light emitting element layer DP-ED. The encapsulation layer ENL may be disposed on the circuit layer DP-CL to seal the light emitting element layer DP-ED. The encapsulation layer ENL may be a thin-film encapsulation layer including a plurality of organic thin-films and inorganic thin-films. The encapsulation layer ENL may include a thin-film encapsulation layer having a laminated structure of an inorganic layer/an organic layer/an inorganic layer. However, the embodiment of the invention is not limited to the laminated structure of encapsulation layer ENL.

As with the mother panel M-DP, the display panel DP may include one surface D-UF and the other surface (or an opposing surface) D-LF opposite to the one surface D-UF. The one surface D-UF may correspond to a top surface of the display panel DP, and the other surface D-LF may correspond to a bottom surface of the display panel DP. The one surface D-UF may be defined by a top surface of the encapsulation layer ENL. The other surface D-LF may be defined by a bottom surface of the base substrate BL. In an embodiment, the base substrate BL, the circuit layer DP-CL, the light emitting element layer DP-ED, and the encapsulation layer ENL may be disposed between the one surface D-UF and the other surface D-UF of the display panel DP.

In an embodiment, the light emitting element layer DP-ED may be disposed on the base substrate BL to face the one surface D-UF. As described above, since the unit panels U-DP overlap the openings M-OP1 and M-OP2, respectively, the light emitting element DP-ED may overlap the corresponding opening of the openings M-OP1 and M-OP2 on the plane defined by the first direction DR1 and the second direction DR2.

In an embodiment, as shown in FIG. 9, the one surface D-UF of the display panel DP may have a stepped portion between the display area AA and the non-display area NAA, but the one surface D-UF is illustrated as a flat surface for convenience of illustration in the mother panel M-DP in FIG. 5B.

Although the unit panel U-DP included in the mother panel M-DP includes only the display panel DP in FIGS. 8 and 9, the embodiment of the invention is not limited thereto. For example, the unit panel U-DP included in the mother panel M-DP may be in a state in which the upper member UM (refer to FIG. 2) is coupled to the display panel DP or in a state in which the upper member UM (refer to FIG. 2) and the window WM (refer to FIG. 2) is coupled to the display panel DP.

FIGS. 10A and 10B are plan views illustrating one component of the apparatus for manufacturing the display apparatus according to an embodiment of the invention. FIGS. 10A and 10B are plan views illustrating a plate PT constituting the molding unit MU.

Referring to FIGS. 5A, 5B, 10A, and 10B together, the molding unit MU may include the plate PT defining a molding space with the frame FM. The plate PT may include a first plate PT1 in which a plurality of holes OH are defined and a second plate PT2 disposed on the second surface SF2 of the frame FM to overlap the plurality of holes OH.

As illustrated in FIGS. 10A and 10B, the first plate PT1 and the second plate PT2 may overlap each other on the plane defined by the first direction DR1 and the second direction DR2. The second plate PT2 may entirely overlap the plurality of holes OH defined in the first plate PT1. In an embodiment where the first plate PT1 includes a plurality of sub-plates PT1-1 and PT1-2, the second plate PT2 may overlap each of the plurality of sub-plates PT1-1 and PT1-2 on the plane. The second plate PT2 may entirely overlap the plurality of holes OH defined in each of the plurality of sub-plates PT1-1 and PT1-2.

As illustrated in FIGS. 10A and 10B, in an embodiment, each of the plurality of holes OH defined in the first plate PT1 may have various shapes. Each of the plurality of holes OH may have a circular shape, an elliptical shape, a polygonal shape, or a closed line shape including at least some curves. In an embodiment, for example, the plurality of holes OH may have a rectangular shape as illustrated in FIG. 10A or may have a linear bar shape or a shape extending in one direction as illustrated in FIG. 10B. Although an embodiment where each of the plurality of holes OH has a shape extending in the first direction DR1 is shown in FIG. 10B as an example, the embodiment is not limited thereto. Also, the number and arrangement direction of the plurality of holes OH may be variously changed.

In an embodiment, the second plate PT2 may include a plurality of protrusions PR corresponding to the shapes of the plurality of holes OH. In an embodiment, for example, when each of the plurality of holes OH has a rectangular shape as illustrated in FIG. 10A, each of the plurality of protrusions PR may have a rectangular shape. In an embodiment, where each of the plurality of holes OH has a shape extending in one direction as illustrated in FIG. 10B, each of the plurality of protrusions PR may have a shape extending in the same direction as an extending direction of each of the plurality of holes OH. However, the embodiment of the invention is not limited thereto. In an embodiment, for example, the plurality of protrusions PR may be omitted depending on process conditions.

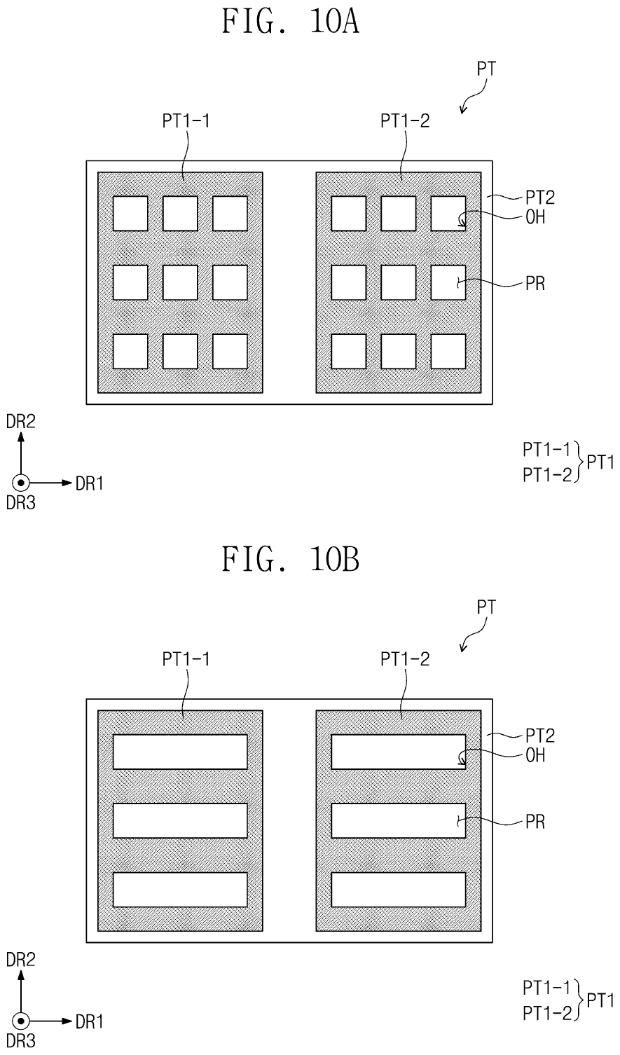

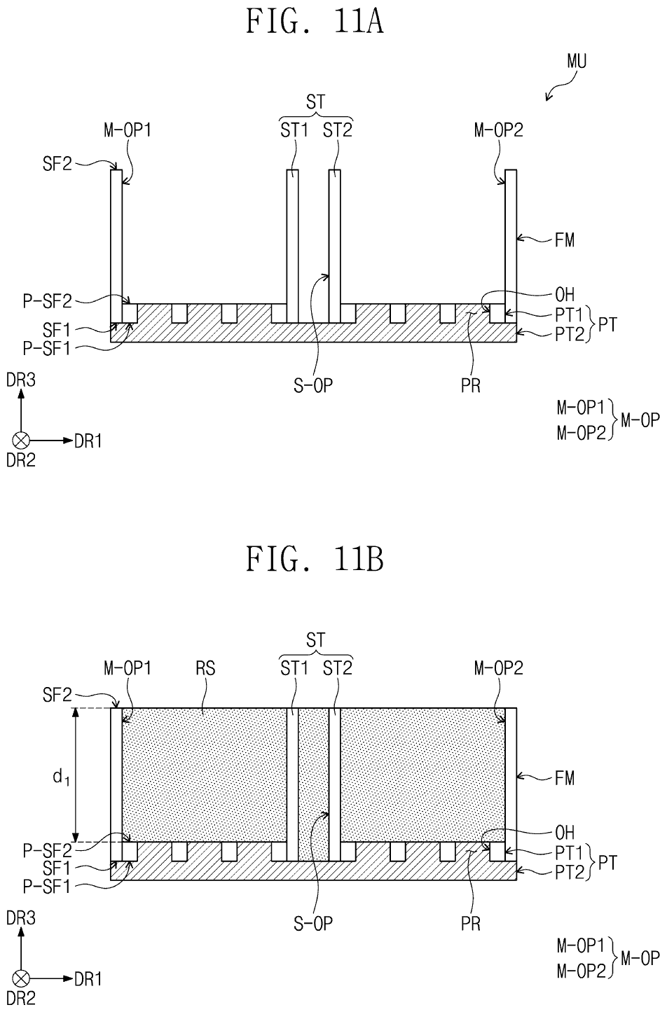

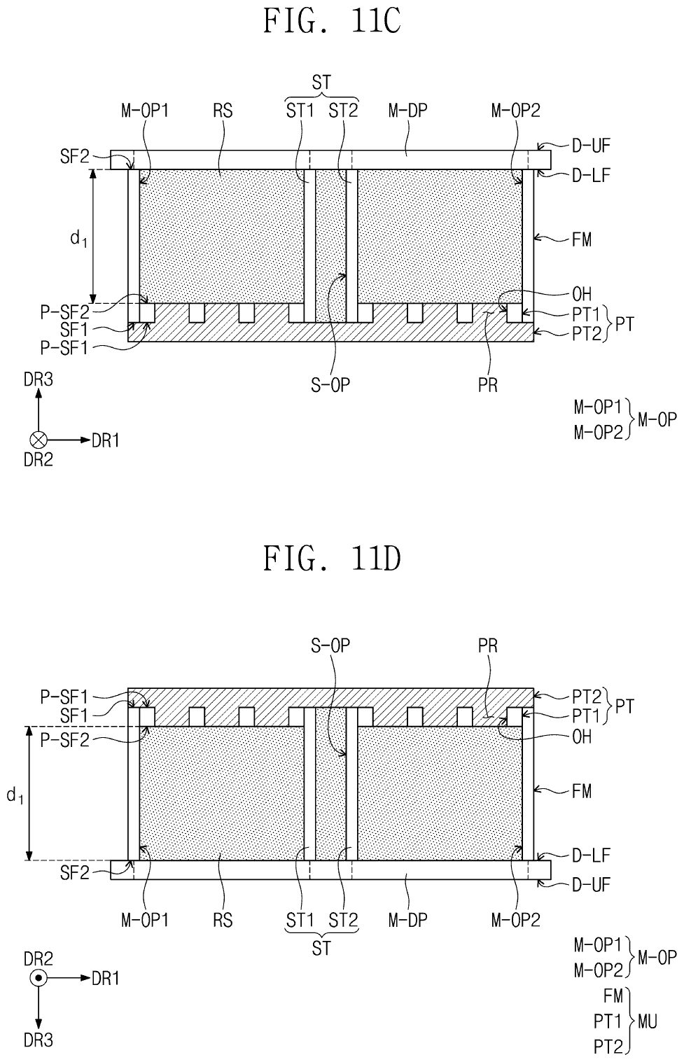

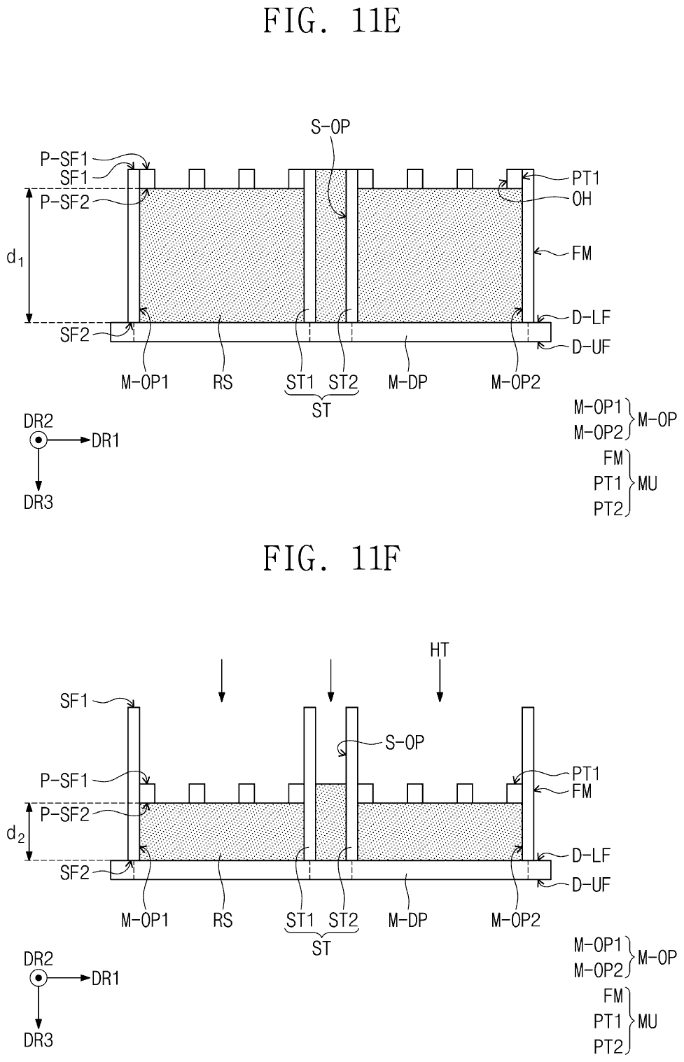

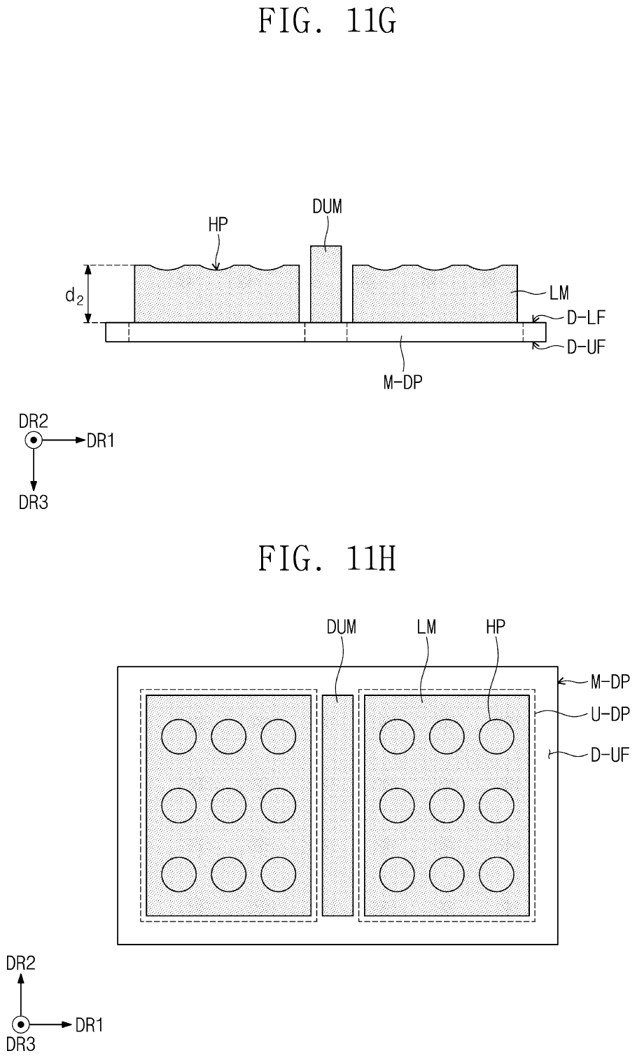

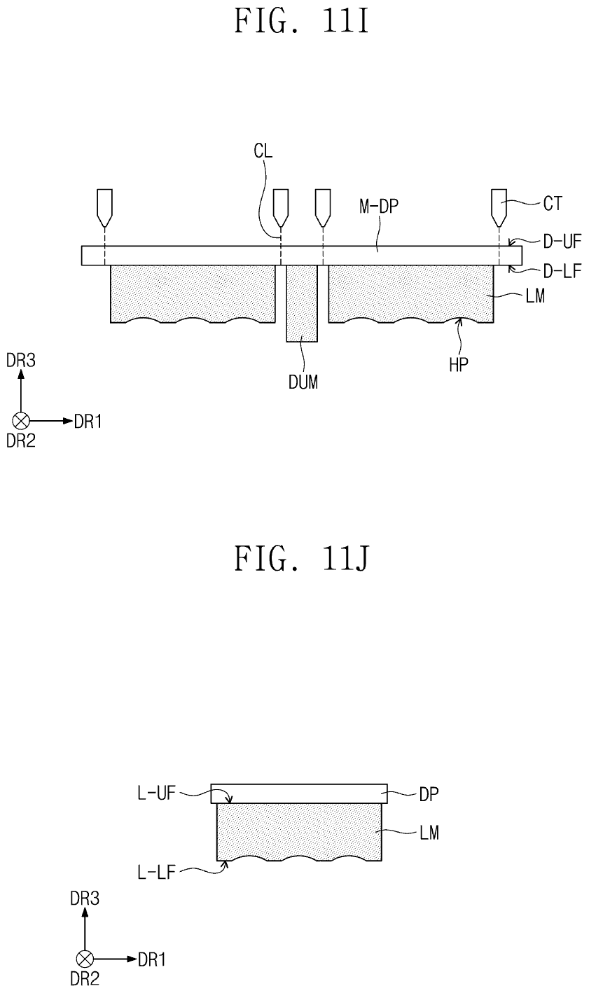

FIGS. 11A to 11J are views illustrating some process of the method for manufacturing the display apparatus according to an embodiment of the invention. Particularly, FIGS. 11A to 11J illustrate a process of forming a protection layer LM disposed below a display panel DP in the display apparatus DD according to an embodiment by using the apparatus for manufacturing the display apparatus according to an embodiment of the invention. FIGS. 11A to 11G, 11I and 11J are cross-sectional views illustrating some process of the method for manufacturing the display apparatus according to an embodiment of the invention. FIG. 11H is a plan view illustrating some process of the method for manufacturing the display apparatus according to an embodiment of the invention. Also, FIG. 11A is a cross-sectional view taken along line I-I′ in FIG. 5A. Hereinafter, the method for manufacturing the display apparatus according to an embodiment of the invention will be described with reference to FIGS. 11A to 11J. Here, the same reference numerals are assigned to the same configuration as those of the display apparatus in FIGS. 1 to 10B, and any repetitive detailed descriptions will be omitted.

The method for manufacturing the display apparatus according to an embodiment of the invention may include: a process of preparing a molding unit including a frame FM, a first plate PT1, and a second plate PT2; a process of providing a resin RS into a molding space defined by the frame FM, the first plate PT1, and the second plate PT2; a process of arranging a mother panel M-DP on a molding unit MU; a process of reversing the molding unit MU and the mother panel M-DP in the vertical direction; a process of removing the second plate PT2 from the molding unit MU; a process of curing the resin RS provided in the molding space; and a process of pressing the resin by moving the first plate PT1 closely to the mother panel M-DP.

Referring to FIGS. 11A and 11B, the method for manufacturing the display apparatus according to an embodiment of the invention includes the preparing of the molding unit MU and the providing of the resin RS to the molding unit MU.

Referring to FIG. 11A, an embodiment of the molding unit MU may include a frame FM and a plate PT. The frame FM may have a first surface SF1 and a second surface SF2, which are opposite to each other in a thickness direction thereof. The first surface SF1 may correspond a bottom surface of the frame FM, and the second surface SF2 may correspond a top surface of the frame FM. The second surface SF2 may define a top surface of the molding unit MU. A mask opening M-OP passing through the frame FM in a direction from the first surface SF1 to the second surface SF2 may be defined in the frame FM. The plate PT may be disposed adjacent to the first surface SF1 of the frame FM. The plate PT may include a first plate PT1 which is disposed in the mask opening M-OP and in which a plurality of holes OH are defined and a second plate PT2 having a plate shape and disposed on the first surface SF1 of the frame FM to overlap the plurality of holes OH. The frame FM, the first plate PT1, and the second plate PT2 may be coupled to each other to define a molding space of the molding unit MU. In this specification, a height of the molding space may represent a vertical distance from a top surface of the first plate PT1 to the second surface SF2 of the frame FM in a state in which the frame FM and the plate PT are coupled to each other.

Referring to FIG. 11B, the method for manufacturing the display apparatus according to an embodiment of the invention may include a process of providing the resin RS into the molding space defined by the frame FM, the first plate PT1, and the second plate PT2. The resin RS may be provided into the molding space in a state in which the molding unit MU is arranged so that the second surface SF2 of the frame FM faces upward.

The resin RS may be provided in various methods. In an embodiment, for example, the resin RS may be provided into the molding space through a nozzle (not shown). The nozzle (not shown) may be disposed above the molding unit MU, and the resin RS may be discharged from the nozzle (not shown) toward the molding space defined in the molding unit MU. A process of providing the resin onto an object to be processed by using a nozzle NZ may be defined as a dispensing printing process. As the dispensing printing process, an inkjet method, a jet valve method, and a slit coating method may be used.

The resin RS may be provided to the mask opening M-OP. In an embodiment where the molding unit MU includes a support ST that divides the mask opening M-OP into a plurality of openings M-OP1 and M-OP2, the resin RS may be provided to each of the divided openings M-OP1 and M-OP2. In an embodiment, where a plurality of supports ST are provided, the resin RS may be provided to a dummy opening S-OP defined between the plurality of supports ST1 and ST2. On the plane (or when viewed in the third direction DR3), the dummy opening S-OP may not overlap the unit panels U-DP (refer to FIG. 8). On the plane, the dummy opening S-OP may correspond to an area between the adjacent unit panels U-DP (refer to FIG. 8). The resin RS provided in the dummy opening S-OP may be provided on a bottom surface D-LF of the mother panel M-DP to be adjacent to edges of the unit panels U-DP (refer to FIG. 8).

An area overlapping the support ST on the bottom surface D-LF of the mother panel M-DP may be an area on which the resin is not provided. The area of the mother panel M-DP, which overlaps the support ST and on which the resin RS is not provided may be an area in which scribing is performed in a subsequent process of cutting the mother panel M-DP.

In an embodiment, the resin RS provided to the molding unit MU may have a first thickness d1. The first thickness di of the resin RS may be substantially equal to a height of the molding space defined in the molding unit MU. The height of the molding space may represent a vertical distance from the top surface of the first plate PT1 to the second surface SF2 of the frame FM in a state in which the frame FM and the plate PT are couped to each other. In an embodiment, the molding space may have a height of about 30 μm or greater to about 700 μm or less. In an embodiment, for example, the molding space may have a height of about 400 μm

The resin RS may include a base resin and a plurality of fillers FP (refer to FIG. 4) dispersed in the base resin. In an embodiment, the base resin may include a thermosetting resin. The same features as those described above in FIG. 4 may be applied to the plurality of fillers included in the resin RS.

Referring to FIG. 11C, the method for manufacturing the display apparatus according to an embodiment of the invention may include a process of arranging the mother panel M-DP on the molding unit MU. As illustrated in FIG. 11C, the mother panel M-DP may be disposed on the second surface SF2 of the frame FM. The bottom surface D-LF of the mother panel M-DP may contact the second surface SF2 of the frame FM. The mother panel M-DP may be seated and fixed on the second surface SF2 of the frame FM. A closed space in which the molding space filled with the resin RS is blocked from the outside may be formed by arranging the mother panel M-DP on the molding unit MU.

On a plane, the openings M-OP1 and M-OP2 defined in the frame FM may be disposed at an inner side than each of the unit panels U-DP (refer to FIG. 8). That is, on the plane defined by the first direction DR1 and the second direction DR2, a planar area of each of the openings M-OP1 and M-OP2 defined in the frame FM may be less than that of each of the unit panels U-DP (refer to FIG. 8). However, the embodiment of the invention is not limited thereto. For example, the planar area of each of the openings M-OP1 and M-OP2 defined in the frame FM may be equal to that of each of the unit panels U-DP (refer to FIG. 8).

Referring to FIG. 11D, the method for manufacturing the display apparatus according to an embodiment of the invention may include a process of reversing the mother panel M-DP on the molding unit MU in the vertical direction or putting the mother panel M-DP on the molding unit MU upside down. The molding unit MU and the mother panel M-DP may be reversed in the vertical direction so that the first surface SF1 of the frame FM faces upward in a state in which the mother panel M-DP is disposed on the second surface SF2 of the frame FM. In the vertically reversed state, the mother panel M-DP may be disposed below the molding unit MU. In the vertically reversed state, the top surface D-UF of the mother panel M-DP may face downward, and the bottom surface D-LF of the mother panel M-DP may face upward.

In the process of vertically reversing the molding unit MU and the mother panel M-DP, the resin RS filled in the molding space may not be separated from the molding space. Since the molding space filled with the resin RS forms the closed space blocked from the outside by the mother panel M-DP, the resin RS may not be separated from the molding space in the process of vertically reversing the molding unit MU and the mother panel M-DP.

Referring to FIG. 11E, the method for manufacturing the display apparatus according to an embodiment of the invention may include a process of exposing the plurality of holes OH defined in the first plate PT1 by removing the second plate PT2.

After vertically reversing the molding unit MU and the mother panel M-DP so that the first surface SF1 of the frame FM faces upward, the second plate PT2 may be removed from the molding unit MU to expose the plurality of holes OH defined in the first plate PT1. When the second plate PT2 is removed, a portion of the resin RS provided to the openings M-OP1 and M-OP2 may be exposed by the plurality of holes OH. Also, as the second plate PT2 is removed, a portion of the resin RS provided in the dummy opening S-OP may be exposed to the outside. The plurality of holes OH may serve to improve heat transfer to the resin RS in a process of curing the resin RS by providing heat to the resin RS, which will be described later. Also, the plurality of holes OH may serve as a path through which a solvent is allowed to be evaporated when the resin RS is thermally cured is easily discharged.

Referring to FIG. 11F, the method for manufacturing the display apparatus according to an embodiment of the invention may include a process of curing the resin RS by providing heat HT and a process of pressing the resin RS by moving the first plate PT1 closely to the mother panel M-DP. In an embodiment, the process of curing the resin RS by providing heat HT and the process of pressing the resin RS by moving the first plate PT1 closely to the mother panel M-DP may be performed at the same time.

The resin RS provided to the openings M-OP1 and M-OP2 and the dummy opening S-OP may be cured by a thermal curing method. As the heat HT is supplied to the resin RS provided in the openings M-OP1 and M-OP2 and the dummy opening S-OP, the resin RS provided to the openings M-OP1 and M-OP2 and the dummy opening S-OP may be cured. As illustrated in FIG. 11F, the heat HT may be provided to the resin RS in a state in which the second plate PT2 is removed and the plurality of holes OH are exposed to the outside.

While the resin RS is cured, the first plate PT1 may be moved closer to the mother panel M-DP. The first plate PT1 may move downward toward the mother panel M-DP, and the resin RS provided in the molding space may be pressed by the movement of the first plate PT1. In an embodiment, the resin RS may have a second thickness d2. The second thickness d2 of the cured resin RS may be different from the first thickness d1 of the resin RS provided in the molding space before cured. The second thickness d2 of the cured resin RS may be less than the first thickness di of the resin RS before cured. In an embodiment, the second thickness d2 may be about 30 μm or greater and about 300 μm or less. In an embodiment, for example, the second thickness d2 may be about 200 μm. In this specification, the second thickness d2 of the cured resin RS may represent a vertical distance from the top surface P-SF2 of the first plate PT1 to the bottom surface of the mother panel M-DP, which is measured in a state in which the resin RS is pressed by the first plate PT1. The second thickness d2 of the cured resin RS may correspond to a thickness of the protection layer LM formed thereafter.

In an embodiment, the resin layer RS may include a thermosetting resin. The thermosetting resin may be contracted when thermally cured. The thermosetting resin may be reduced in volume due to solvent evaporation as the curing is performed. Here, when an evaporation efficiency of the solvent is low, since a degree of contraction of the solvent is different throughout the resin RS, a uniform thin-film may not be obtained. In an embodiment of the invention, when the resin RS is cured, the solvent evaporation efficiency may be improved as the resin RS is pressed by the first plate PT1 having the plurality of holes OH, and a degree of contraction of the solvent throughout the resin RS may be substantially uniform. Accordingly, the protection layer LM having uniform thin-film characteristics may be formed.

Referring to FIGS. 11G and 11H, the method for manufacturing the display apparatus according to an embodiment of the invention may include a process of removing the molding unit MU. After the protection layer LM is formed, the molding unit MU may be removed from the mother panel M-DP. Accordingly, the protection layer LM may be remained on the bottom surface D-LF of the mother panel M-DP.

Referring to FIGS. 11F to 11H together, as the resin RS provided in each of the openings M-OP1 and M-OP2 is cured, a plurality of protection layers LM may be formed on the bottom surface D-LF of the mother panel M-DP in correspondence to the plurality of unit panels U-DP. The protection layers LM may be disposed on the bottom surfaces of the unit panels U-DP, respectively. Also, the resin RS provided in the dummy opening S-OP may be cured to form a dummy layer DUM on the bottom surface of the mother panel M-DP.

FIG. 11H is a plan view illustrating the protection layer LM and the dummy layer DUM disposed on the bottom surface D-LF of the mother panel M-DP in FIG. 11G. In FIG. 11H, edges of the unit panel U-DP is expressed by a dotted line, and the edges of the unit panel U-DP may serve as a cutting line in a cutting process that will be described later.

Referring to FIG. 11H, on the plane, an area of each of the plurality of protection layers LM may be less than that of each of the plurality of unit panels U-DP. That is, on the plane, an edge of the protection layer LM may be disposed inside the edge of the unit panel U-DP. On the plane, the protection layer LM may have a shape corresponding to the openings M-OP1 and M-OP2. The dummy layer DUM may be formed on a portion corresponding to the area between adjacent unit panels U-DP in the bottom surface D-LF of the mother panel M-DP. On the plane, the dummy layer DUM may have a shape corresponding to the dummy openings S-OP. On the plane, the dummy layer DUM may not overlap the unit panels U-DP. The dummy layer DUM may be disposed at an outer side than each of the unit panels U-DP.

In an embodiment, a pattern corresponding to the plurality of holes OH may be formed on the bottom surface of the protection layer LM. The pattern may be a transfer pattern formed in the process of pressing the resin RS by the first plate PT1. On the plane, the pattern formed on the bottom surface of the protection layer LM may have a shape corresponding to that of the plurality of holes OH. A portion of the bottom surface of the protection layer LM, which is pressed by the first plate PT1, may form a flat surface. A portion of the bottom surface of the protection layer LM, which overlaps the plurality of holes OH, may have a pattern corresponding to the plurality of holes OH. The pattern may be recessed or protrude from the bottom surface of the protection layer LM. In an embodiment, for example, as illustrated in FIG. 11G, the protection layer LM may include a plurality of grooves HP recessed from the bottom surface of the protection layer LM. A portion of the bottom surface of the protection layer LM, which overlaps the plurality of holes OH, may have a curing rate and a solvent evaporation rate, which are different from those of a portion that does not overlap the plurality of holes OH. Accordingly, a pattern corresponding to a shape of a plurality of holes OH may be formed on the bottom surface of the protection layer LM.

Referring to FIGS. 11I and 11J, the method for manufacturing the display apparatus according to an embodiment of the invention may further include a process of cutting the mother panel M-DP.

After the process of removing the molding unit MU from the mother panel M-DP, a process of cutting the mother panel M-DP along a cutting line corresponding to an edge of each of the plurality of unit panels U-DP is performed.

Referring to FIG. 11I, the mother panel M-DP may be turned over in the third direction DR3 or put upside down. That is, the mother panel M-DP may be vertically reversed. Accordingly, the top surface D-UF of the mother panel M-DP may face upward, and the bottom surface D-LF of the mother panel M-DP may face downward.

A cutting tool CT may be disposed on the mother panel M-DP. The cutting tool CT may be provided on the top surface D-UF of the mother panel M-DP. In an embodiment, for example, the cutting tool CT may include a knife or a blade. However, the embodiment of the invention is not limited thereto.

In FIG. 11I, the edges of the unit panels U-DP are expressed by dotted lines, and the edges may define the cutting line CL of the mother panel M-DP. In each of the unit panels U-DP, the cutting line CL may be defined between the protection layer LM and the dummy layer DUM. The cutting tool CT may move along the cutting line CL to separate the unit panels U-DP from the mother panel M-DP. Accordingly, the plurality of unit panels U-DP may be separated into individual unit panels U-DP illustrated in FIG. 11J.

In general, a screen printing method using a wire mesh mask may be used to form the protection layer LM on a rear surface of the display panel DP. The screen printing method places a screen mask having holes defined in a predetermined pattern on a substrate, supplies a resin onto the screen mask, and presses the resin by using a pressing unit such as a squeegee, thereby allowing the resin to pass through the holes in the mask and forming a predetermined pattern on the substrate. However, since the screen mask uses a steel wire, a deflection may occur due to tension, thereby limiting an application thickness of the resin. Thus, the protection layer having a thickness greater than a certain level may not be realized. Also, when the protection layer LM is formed by using a film attachment method instead of the resin application method, since layers having a heat dissipation function, a light blocking function, an electromagnetic wave blocking function, and an impact absorption function are required to be separately provided on the rear surface of the display panel DP, which requires a plurality of processes. Thus, the process efficiency may be reduced, and the thickness of the protection layer LM increases to reduce miniaturization or slimness of the display apparatus DD.

The apparatus for manufacturing the display apparatus and the method for manufacturing the display apparatus according to an embodiment of the invention use the molding unit which has a predetermined height and in which the molding space for accommodating the resin is defined to form the protection layer on the rear surface of the display panel, thereby securing the thickness enough to provide structural stability of the protection layer. Also, according to an embodiment of the invention, the protection layer may be formed by directly applying the resin containing the plurality of fillers that perform multiple functions on the rear surface of the display panel. Accordingly, the process may be simplified, the thickness of the display apparatus may be reduced, the components may be simplified, and the manufacturing process efficiency may be improved. Also, the method for manufacturing the display apparatus according to an embodiment of the invention may use the plate in which the plurality of holes are defined and which is vertically movable in the molding space to form the protection layer having the uniform thin-film characteristics on the rear surface of the display panel. The heat transfer to the resin provided in the molding space may be improved by the plurality of holes, and uniformity of the heat transfer may increase to increase the curing efficiency. Also, the solvent evaporated from the resin during the thermal curing may be easily discharged through the plurality of holes, thereby improving the durability of the protection layer formed thereafter. Since the volume of the resin decreases by the solvent evaporation during the thermal curing, the uniform thin-film may not be obtained in case of a low evaporation efficiency. However, according to an embodiment of the invention, since the evaporation of the solvent may be generated efficiently through the plurality of holes, the uniform thin-film may be formed, and the durability of the protection layer may be improved. Thus, the display apparatus having the improved reliability may be provided.

The display apparatus according to the embodiment of the invention may obtain the effect of reducing the thickness of the display apparatus through simplifying the plurality of functional members by including the protection layer performing multiple functions and disposed below the display panel.

The apparatus for manufacturing the display apparatus according to the embodiment of the invention may improve the efficiency of the process of manufacturing the display apparatus and provide the display apparatus including the protection layer having the uniform thin-film feature by including the plate in which the plurality of holes are defined and which is movable in the vertical direction in the molding space.

The method for manufacturing the display apparatus according to the embodiment of the invention may form the protection layer having the uniform thin-film feature on the rear surface of the display panel by using the plate in which the plurality of holes are defined and which is movable in the vertical direction in the molding space. Thus, the display apparatus having the improved reliability may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display apparatus, the apparatus comprising:
a molding unit comprising a frame including a first surface and a second surface opposite to the first surface, wherein a mask opening passing from the first surface to the second surface is defined in the frame; and a plate disposed adjacent to the first surface of the frame, wherein a molding space is defined by the frame and plate,
wherein the plate comprises:
a first plate disposed in the mask opening, wherein a plurality of holes are defined in the first plate; and
a second plate having a plate shape and disposed on the first surface of the frame to overlap at least the plurality of holes on a plane, and
the first plate moves in a direction perpendicular to each of the first surface and the second surface in a space between the first surface and the second surface of the frame.

2. The apparatus of claim 1, wherein the second plate is coupled to the frame in a separable manner.

3. The apparatus of claim 1, wherein the second plate comprises a plurality of protrusions inserted into the plurality of holes defined in the first plate, respectively.

4. The apparatus of claim 1, further comprising a control unit which controls a movement of the first plate.

5. The apparatus of claim 1, wherein the molding unit further comprises a support disposed in the mask opening and connected to the frame to divide the mask opening into a plurality of openings.

6. The apparatus of claim 5, wherein the support is integrally formed with the frame as a single unitary and indivisible part.

7. The apparatus of claim 5, wherein the mask opening includes a first opening and a second opening, which are separated from each other by the support,
the first plate comprises:
a first sub-plate disposed in the first opening; and
a second sub-plate disposed in the second opening, and
each of the first sub-plate and the second sub-plate moves in the direction perpendicular to each of the first surface and the second surface.

8. The apparatus of claim 1, wherein a mother panel is disposed on the second surface of the frame,
the mother panel comprises:
one surface;
an opposing surface opposite to the one surface;
a substrate disposed between the one surface and the opposing surface; and
a display element layer disposed on the substrate to face the one surface and between the one surface and the opposing surface to overlap the mask opening, and the opposing surface of the mother panel contacts the frame.

9. The apparatus of claim 1, wherein the first plate comprises a metal.

10. The apparatus of claim 1, wherein the first plate comprises a same material as the frame.

11. A method for manufacturing a display apparatus, the method comprising:
preparing a molding unit comprising a frame in which a mask opening passing from a first surface to a second surface thereof, which are opposite to each other, is defined, a first plate which is disposed in the mask opening and in which a plurality of holes are defined, and a second plate having a plate shape and disposed on the first surface of the frame to overlap the plurality of holes on a plane;
providing a resin into a molding space defined by the frame, the first plate, and the second plate in a state in which the second surface of the molding unit is arranged to face upward;
arranging a mother panel on the second surface of the frame;
reversing the molding unit and the mother panel upside down such that the first surface of the frame faces upward in a state in which the mother panel is disposed on the second surface of the frame;
exposing the plurality of holes defined in the first plate by removing the second plate;
curing the resin by supplying heat to the resin;
pressing the resin by moving the first plate in a direction towards the mother panel; and
removing the molding unit.

12. The method of claim 11, wherein the supplying the heat to the resin and the pressing the resin are simultaneously performed.

13. The method of claim 11, wherein the mother panel comprises:
one surface;
an opposing surface opposite to the one surface;
a substrate disposed between the one surface and the opposing surface; and
a display element layer disposed on the substrate to face the one surface and between the one surface and the opposing surface to overlap the mask opening, and
the opposing surface of the mother panel contacts the frame.

14. The method of claim 11, wherein a protection layer is formed through the curing the resin and the pressing the resin, and
the protection layer has a thickness less than a thickness of the resin before the curing the resin.

15. The method of claim 14, wherein in the pressing the resin, a pattern corresponding to the plurality of holes is formed on a bottom surface of the protection layer, which is spaced apart from the mother panel.

16. The method of claim 11, wherein the mother panel comprises a plurality of unit panels, and
the molding unit further comprises a support disposed in the mask opening to divide the mask opening into a plurality of openings corresponding to the plurality of unit panels, respectively.

17. The method of claim 16, wherein the first plate comprises a plurality of sub-plates disposed in the plurality of openings, respectively.

18. The method of claim 16, further comprising cutting the mother panel along a cutting line corresponding to an edge of each of the plurality of unit panels after the removing the molding unit.

19. The method of claim 11, wherein the resin comprises a base resin including a thermosetting resin and a plurality of fillers dispersed in the base resin.

20. A display apparatus comprising:
a display panel; and
a protection layer comprising:
a base layer disposed on a rear surface of the display panel and including a thermosetting resin; and
a plurality of fillers dispersed in the base layer,
wherein the protection layer has a top surface adjacent to the rear surface of the display panel and a bottom surface opposite to the top surface and is spaced apart from the rear surface of the display panel, and
the protection layer includes a plurality of grooves defined on the bottom surface thereof.
